(19) United States
(12) Patent Application Publication
(10) Pub. No.: US 2016/0061910 A1
(43) Pub. Date: Mar. 3, 2016

(54) ELECTRONIC DEVICE AND DETECTION METHOD OF POWER CAPACITY

(71) Applicant: Acer Incorporated, New Taipei City (TW)

(72) Inventor: Shu-Wei Peng, New Taipei City (TW)

(21) Appl. No.: 14/582,211

(22) Filed: Dec. 24, 2014

(30) Foreign Application Priority Data
Aug. 29, 2014 (TW) 103129891

(51) Int. Cl. G01R 31/36

(52) U.S. Cl. CPC G01R 31/3682; G01R 31/3651

(57) ABSTRACT

An electronic device and a detection method of power capacity are provided. The electronic device includes a battery and a power management unit coupled to the battery. The power management unit reads an output voltage of the battery, and determines whether a variation of the output voltage of the battery within a time interval is greater than a threshold. When the power management unit determines that the variation of the output voltage of the battery within the time interval is greater than the threshold, the power management unit calculates a remaining power capacity of the battery according to the output voltage and the variation of the output voltage within the time interval.

### CROSS-REFERENCE TO RELATED APPLICATION

This application claims the priority benefit of Taiwan application serial no. 103129891, filed on Aug. 29, 2014. The entirety of the above-mentioned patent application is hereby incorporated by reference herein and made a part of this specification.

### BACKGROUND OF THE INVENTION

1. Field of the Invention

The invention relates to an electronic device, and more particularly, relates to an electronic device and a detection method of power capacity.

2. Description of Related Art

In a handheld electronic device such as a smart phone and a tablet computer, because a power source is usually a battery in the handheld electronic device, a power management thereof has always been an important issue for designers of the handheld electronic device. Also, a current power capacity of the battery displayed on a user interface is one of the most concerned items for a user when using the handheld electronic device.

In the existing handheld electronic device, the power capacity of the battery in the handheld electronic device is displayed in percentages or represented by a proportion icon of the battery. Said percentage or the proportion icon of the battery display the percentage of the power capacity of the battery mainly according to a measured battery open circuit voltage (OCV). The so-called battery open circuit voltage is obtained by measuring an output voltage of the battery when the handheld electronic device is in a light-load state (e.g., before the handheld electronic device starts its operating system or when the operating system enters a sleep mode). After the battery open circuit voltage is measured, the battery open circuit voltage is converted into a digital signal by an analog-digital converter in a power management unit (e.g., a POWER IC, etc.). Subsequently, a current remaining power capacity of the battery in an electronic device may be calculated by looking up a relation table of the battery open circuit voltage and the power capacity of the battery.

FIG. 1 is a schematic diagram illustrating relationship between the battery open circuit voltage and the power capacity of the battery of a lithium battery. Referring to FIG. 1, in lithium battery, the relationship between the battery open circuit voltage and the power capacity is linear. When it is measured that the battery open circuit voltage is between 3.8V to 4.2V, the electronic device may determine that the current power capacity of the battery is between 75% to 100%; and when it is measured that the battery open circuit voltage is between 3.4V to 3.8V, the electronic device may determine that the current power capacity of the battery is between 50% to 75%; and the rest may be deduced by analogy. Yet, in case the battery outputs in a load state, the output voltage would drop due to the load, and thus such output voltage cannot reflect the actual remaining power capacity of the battery in real time. Therefore, when the electronic device is in a state with load, the electronic device may calculate the current remaining power capacity of the battery according to the battery open circuit voltage measured previously and information regarding the load and a current supplying current.

However, a discharge characteristic of the battery may cause errors to occur on the power capacity of the battery calculated when using the battery open circuit voltage in the light-load state. For example, during operation of the operating system of the handheld electronic device, if the battery suddenly falls out or the battery suddenly being removed, the battery requires a recovery time (e.g., approximately 30 minutes as for the lithium battery) in order to return from the load state back to a no-load state, so that the output voltage of the battery may be recovered back to the stable battery open circuit voltage. It may result in serious misjudgment if the electronic device reads the output voltage of the battery during the recovery time to serve as the battery open circuit voltage for determining the current power capacity of the battery.

### SUMMARY OF THE INVENTION

The invention is directed to an electronic device and a detection method of power capacity, which are capable of determining a current power capacity of a battery.

An electronic device according to the invention includes a battery and a power management unit coupled to the battery. The power management unit reads an output voltage of the battery, and determines whether a variation of the output voltage of the battery within a time interval is greater than a first threshold. When the power management unit determines that the variation of the output voltage of the battery within the time interval is greater than the first threshold, the power management unit calculates a remaining power capacity of the battery according to the output voltage and the variation of the output voltage within the time interval.

A detection method of power capacity according to the invention is adapted for an electronic device having a battery, and includes the following steps. First of all, an output voltage of the battery is read, and whether a variation of the output voltage of the battery within a time interval is greater than a first threshold is determined. Next, when it is determined that the variation of the output voltage of the battery within the time interval is greater than the threshold, a remaining power capacity of the battery is calculated according to the output voltage and the variation of the output voltage within the time interval.

Based on above, the electronic device and the detection method of the power capacity provided by the invention are capable of accurately estimating the current remaining power capacity of the battery according to the variation of the output voltage of the battery in the electronic device.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating the relationship between the battery open circuit voltage and the power capacity of the battery of a lithium battery.

FIG. 2 is a block diagram illustrating an electronic device according to an embodiment of the invention.

FIG. 3 is a flowchart illustrating a detection method of power capacity according an embodiment of the invention.

FIG. 4 is a schematic diagram illustrating a relationship between the output voltage and time according to an embodiment of the invention.

FIG. 5 is a block diagram illustrating an electronic device according to an embodiment of the invention.

FIG. 6 is a flowchart illustrating steps in a detection method of power capacity according an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 2 is a block diagram illustrating an electronic device according to an embodiment of the invention. Referring to FIG. 2, an electronic device 10 includes a battery 110 and a power management unit 120 coupled to the battery 110. The power management unit 120 reads an output voltage OV of the battery 110, and determines whether a variation of the output voltage OV of the battery 110 within a time interval is greater than a first threshold. When the power management unit 120 determines that the variation of the output voltage OV of the battery 110 within the time interval is greater than the first threshold, the power management unit 120 calculates a remaining power capacity of the battery 110 according to the output voltage OV and the variation of the output voltage OV within the time interval.

FIG. 3 is a flowchart illustrating a detection method of power capacity according an embodiment of the invention, and the detection method of power capacity is adapted for an electronic device having a battery, such as the electronic device 10 depicted in FIG. 2. Referring to FIG. 3, first, in step S201, an output voltage of the battery is read, and whether a variation of the output voltage of the battery within a time interval is greater than a first threshold is determined. Next, in step S202, when it is determined that the variation of the output voltage of the battery within the time interval is greater than the threshold, a remaining power capacity of the battery is calculated according to the output voltage and the variation of the output voltage within the time interval.

In brief, the power management unit 120 in the electronic device 10 may determine whether the output voltage OV of the battery 110 is the output voltage OV in a recovery period or the battery open circuit voltage in a stable state by using the variation of the output voltage OV of the battery 110 with the time interval (e.g., within 1 second). If the variation of the output voltage OV is greater than the first threshold, the power management unit 120 may determine that the battery 110 is in the recovery period, such that the power management unit 120 may calculate the remaining power capacity of the battery 110 by using the output voltage OV currently read and aforesaid variation.

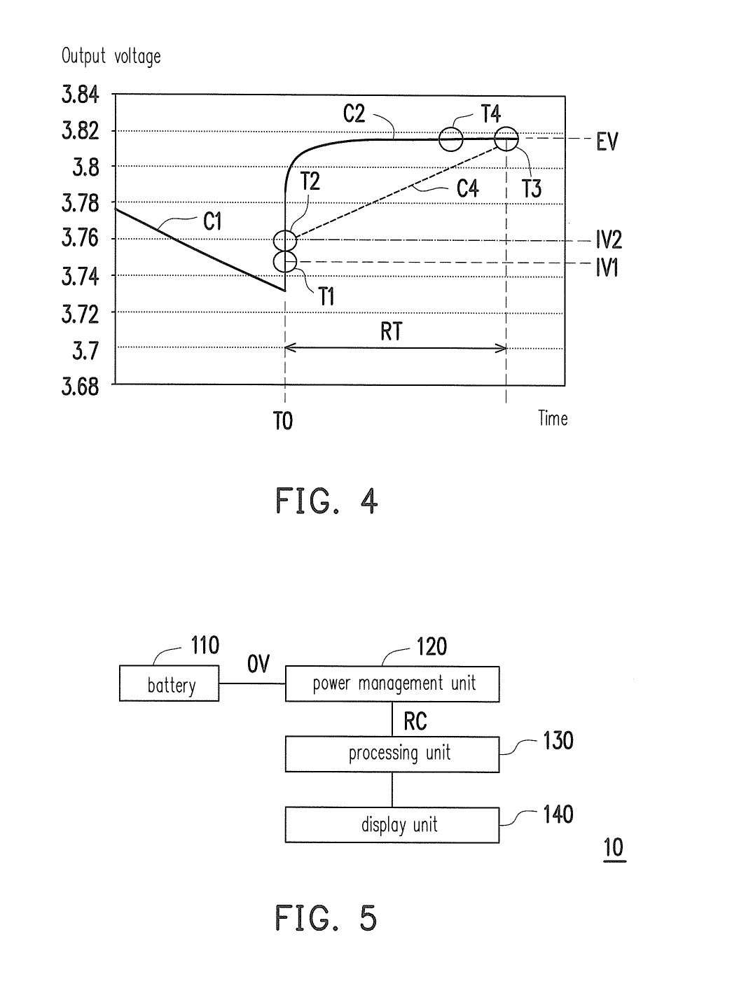

FIG. 4 is a schematic diagram illustrating a relationship between the output voltage and time according to an embodiment of the invention. In the example depicted in FIG. 4, the battery 110 of the electronic device 10 discharges in a load state (i.e., a working state with load) before a time point T0 (corresponding to a segment C1), and then power is cut off at the time point T0 due to certain specific conditions (e.g., the battery suddenly falls out, the battery suddenly being removed or other unknown reasons) which makes the battery 110 is open circuit in a no-load state after the time point T0. It is assumed that after the battery 110 is installed back to the electronic device 10 by a user, the user intends to start an operating system (herein, a time possibly spent on installing the battery 110 back to the electronic device 10 is ignored). In this case, before the operating system starts to be operated (i.e., before the battery 110 outputs in the load state), the power management unit 120 reads a first instantaneous voltage IV1 at a time point T1 and a second instantaneous voltage IV2 at a time point T2, respectively, within the time interval (e.g., 1 second). Accordingly, the power management unit 120 is capable of calculating a variation ΔV according to the first instantaneous voltage IV1 and the second instantaneous voltage IV2. The variation ΔV may be expressed as an equation (1) below.

$$Δ V = \frac{d V}{d t} = \frac{( IV 2 - IV 1 )}{( T 2 - T 1 )} \qquad ( 1 )$$

Herein, the time points T1 and T2 represent the time points for reading the first instantaneous voltage IV1 and reading the second instantaneous voltage IV2, respectively (i.e., a starting time point and an end time point of the time interval).

Accordingly, the power management unit 120 may calculate to derive an estimated voltage EV when the recovery time is ended (i.e., the output voltage OV detectable at a time point T3) by using the first instantaneous voltage IV1 and reading the second instantaneous voltage IV2 and the variation ΔV of the output voltage OV. The estimated voltage EV should be close or equal to the battery open circuit voltage corresponding to the current remaining power capacity of the battery. The estimated voltage EV may be expressed as an equation (2) below.

$$EV = IV 2 + {\int }_{T 0}^{R T} Δ V d t \qquad ( 2 )$$

Herein, RT is the recovery time.

The equation (2) may be calculated using various simplified calculating methods. The most simple method to calculate the estimated voltage EV is to assume that there is a straight line (i.e., a segment C4) between the time point T2 and the time point T3, and the estimated voltage EV would be the multiplication of the variation ΔV and the recovery time RT.

In the present embodiment, the recovery time is set to 30 minutes (e.g., corresponding to the lithium battery), and the first threshold is as equal to 4 μV/sec. Herein, the value of the first threshold is correspondingly close to one percent of a power capacity other battery. Yet, the value of the first threshold may also be set in correspondence to different percentages of the power capacity of the battery, or may be set based on battery characteristic of a battery other than the lithium battery.

In this example, within the time interval, the second instantaneous voltage IV2 measured by the power management unit 120 is 3.76V, and the variation ΔV calculated by the power management unit 120 is 33 μV/sec. Accordingly, the power management unit 120 may determine that the variation ΔV of the output voltage OV is greater than the first threshold, and thereby calculate the estimated voltage EV. Hence, the estimated voltage EV would be equal to:

$$EV = IV + {\int }_{T 0}^{RT} Δ V d t = 3.76 + 33 μV \times 30 Min = 3.76 V + 59 mV = 3.819 V \qquad ( 3 )$$

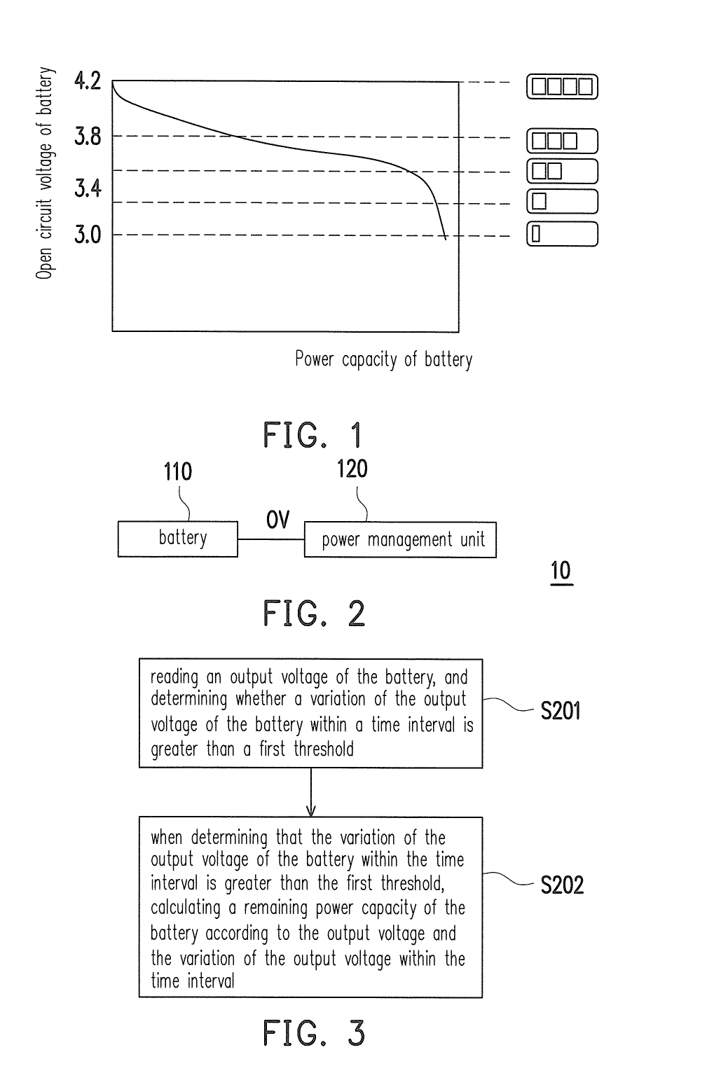

The power management unit 120 may further obtain the current remaining power capacity of the battery 110 through a conversion according to the estimated voltage EV (e.g., in view of FIG. 1, it can be known that 3.819V is correspondingly close to 75% of the power capacity of the battery 110).

On the other hand, in view of a segment C2, the variation of the output voltage OV in the recovery time RT is a non-proportional variation. Therefore, another simplified calculating method for the equation (2) is to divide the recovery time RT into three stages which are a low-speed rising stage, a medium-speed rising stage and a high-speed rising stage. When the power management unit 120 determines that the variation ΔV of the output voltage OV is greater than the first threshold, the power management unit 120 further determines whether the variation ΔV of the output voltage OV is also greater than a second threshold or a third threshold. When the variation ΔV of the output voltage OV is between the first threshold and the second threshold, the power management unit 120 determines whether the variation ΔV of the output voltage OV is in the low-speed rising stage. Similarly, when the variation ΔV of the output voltage OV is between the second threshold and the third threshold, or the variation ΔV of the output voltage OV is greater than the third threshold, the power management unit 120 determines whether the variation ΔV is in the medium-speed rising stage or the high-speed rising stage respectively.

With respect to aforesaid three stages (the low-speed rising stage, the medium-speed rising stage and the high-speed rising stage), the power management unit 120 may set preset variations and preset time intervals for the three states respectively. For example, with the recovery time RT being set to 30 minutes, the power management unit 120 may further set the time intervals for the low-speed rising stage, the medium-speed rising stage and the high-speed rising stage to be 5 minutes, 15 minute and 10 minute respectively together with the corresponding preset variations. As shown in the example of FIG. 4, the time interval between the time points T1 and T2 is still in the high-speed rising stage, and thus the estimated voltage EV is equal to: the preset variation in the high-speed rising stage multiplied by 10 minutes+the preset variation in the medium-speed rising stage multiplied by 15 minutes+the preset variation in the low-speed rising stage multiplied by 5 minutes+the second instantaneous voltage IV2.

It is assumed that a relationship between the variation ΔV of the output voltage OV and the first threshold, the second threshold and the third threshold is determined by the power management unit 120 at time point T4, the power management unit 120 may then determine that the variation ΔV of the output voltage OV is between the first threshold and the second threshold, and the variation ΔV of the output voltage OV is in the low-speed rising stage. Therefore, the estimated voltage EV is equal to the output voltage OV at the time point T4 plus the preset variation in the slow-speed rising stage multiplied by 5 minutes. The invention is not limited to aforementioned calculating methods, and the calculating methods may be adjusted according to actual demands. For example, an amount of stages in the recovery time, the time corresponding to each of the stages and the preset variations may all be adjusted depending upon actual situations or different characteristics of the batteries being adopted.

FIG. 5 is a block diagram illustrating an electronic device according to an embodiment of the invention. Different from the embodiment depicted in FIG. 2, the electronic device 10 in the embodiment depicted in FIG. 5 further includes a processing unit 130 coupled to the power management unit 120 and a display unit 140 coupled to the processing unit 130. In the present embodiment, the processing unit 130 obtains a remaining power capacity RC of the battery 110 from the power management unit 120, and displays the remaining power capacity RC through the display unit 140. The remaining power capacity RC may be displayed through the display unit 140 in various ways. Herein, the remaining power capacity RC may be converted into an object on a user interface on the operating system operated by the processing unit 130, which is displayed in a general operating mode or on a locked screen. The object may be a battery icon accompanying a number showing the percentage of the remaining power capacitor RC, or a battery icon which displays different lengths corresponding to the remaining power capacity RC, but the invention is not limited thereto. In another embodiment of the invention, the processing unit 130 may obtain the battery open circuit voltage (e.g., the output voltage OV in the stable state) or the estimated voltage EV from the power management unit 120, so that the processing unit 130 may convert the battery open circuit voltage or the estimated voltage EV into the remaining power capacity RC, but the invention is not limited thereto.

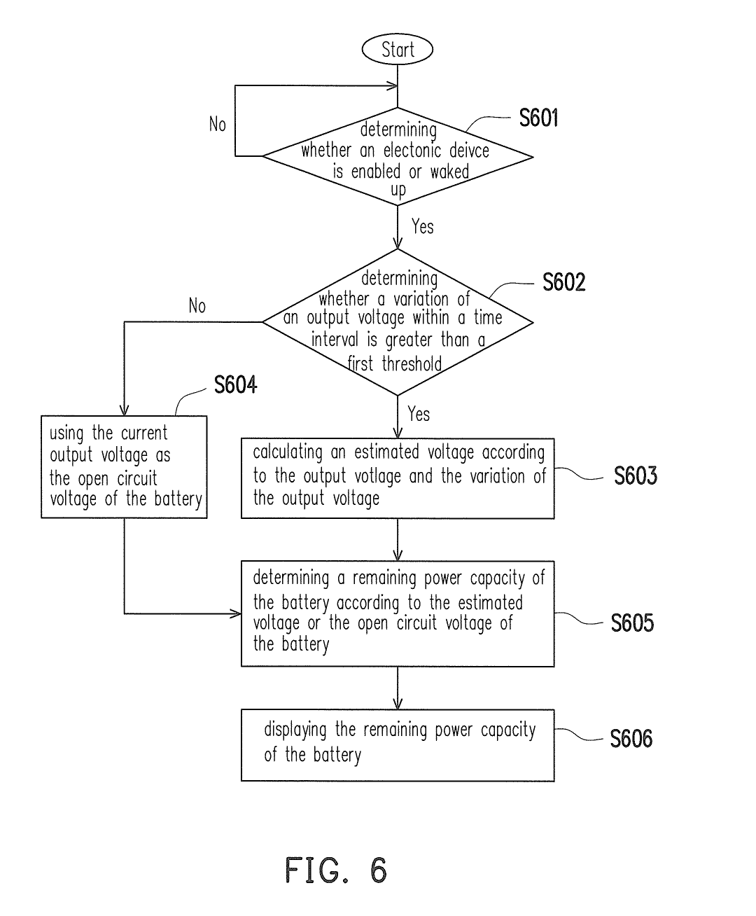

FIG. 6 is a flowchart illustrating steps in a detection method of power capacity according an embodiment of the invention. In comparison with the embodiment depicted in FIG. 3, the embodiment depicted in FIG. 6 provides the implementation in more details. Referring to FIG. 5 and FIG. 6, first, the power management unit 120 continuously determines whether an electronic device is enabled or waked up (more generally, determines whether the battery 110 is switched from the light-load state (or no-load state) to the load state) (step S601). If yes, the power management unit 120 determines whether a variation of an output voltage within a time interval is greater than a first threshold (step S602). If the variation of the output voltage within the time interval is greater than the first threshold, the power management unit 120 calculates an estimated voltage by using the calculating method depicted in FIG. 4 or other calculating methods according to the output voltage OV at the time and the variation of the output voltage within the time interval (step S603).

If the power management unit 120 determines that the variation of the output voltage within the time interval is less than the first threshold, it indicates that the current output voltage of the battery 110 is stable, such that the power management unit 120 may directly set the present output voltage OV (or the first instantaneous voltage, the second instantaneous voltage or an average value thereof which are read in step S602) to be the battery open circuit voltage (step S604). Then, the power management unit 120 determines the current remaining power capacity RC of the battery 110 according to the estimated voltage or the battery open circuit voltage (step S605). Subsequently, the processing unit 130 obtains the remaining power capacity RC of the battery 110 from the power management unit 120, and displays the current remaining power capacity RC of the battery 110 through the display unit 140 (S606).

In summary, the invention provides an electronic device and a detection method of power capacity, which are capable of determining whether the current output voltage of the battery is in the recovery time, and thereby determining the current remaining power capacity of the battery correctly. When the electronic device is rapidly switched between the operating mode and the sleep mode, or when the battery of the electronic device is of a movable design (i.e., the user is able to voluntarily remove or replace the battery) and the battery suddenly falls out or the battery suddenly being removed during operation of the operating system of the electronic device, the electronic device can still determine the remaining power capacity of the battery at the time by using technical solutions provided by the invention, so as to provide the most accurate information to the user in order to further improve a user experience of the electronic device.

Although the present invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device, comprising:
a battery;
a power management unit, coupled to the battery,
wherein the power management unit reads an output voltage of the battery, and determines whether a variation of the output voltage of the battery within a time interval is greater than a first threshold, and
when the power management determines that the variation of the output voltage of the battery within the time interval is greater than the first threshold, the power management unit calculates a remaining power capacity of the battery according to the output voltage and the variation of the output voltage within the time interval.

2. The electronic device according to claim 1, wherein
the power management unit detects a first instantaneous voltage and a second instantaneous voltage within the time interval, and obtains the variation of the output voltage according to the first instantaneous voltage and the second instantaneous voltage; and
the power management unit calculates the remaining power capacity of the battery according to the second instantaneous voltage, the variation of the output voltage within the time interval, and a first recovery time.

3. The electronic device according to claim 2, wherein
when the power management unit determines that the variation of the output voltage of the battery within the time interval is less than the first threshold, the power management unit converts the second instantaneous voltage in order to obtain the remaining power capacity of the battery.

4. The electronic device according to claim 2, wherein
the power management unit determines whether the variation of the output voltage is greater than the first threshold and a second threshold, wherein the second threshold is greater than the first threshold;
when the variation of the output voltage is greater than the first threshold and the second threshold, the power management unit calculates the remaining power capacity of the battery according to the second instantaneous voltage, a first preset variation, a first preset recovery interval, a second preset variation and a second preset recovery interval.

5. The electronic device according to claim 1, wherein
the first threshold corresponds to one percent of a power capacity of the battery.

6. The electronic device according to claim 1, wherein
when the electronic device is enabled, the power management unit reads the output voltage of the battery, and determines whether the variation of the output voltage of the battery within the time interval is greater than the first threshold.

7. The electronic device according to claim 1, wherein the electronic device further comprises:
a display unit; and
a processing unit, coupled to the display unit and the power management unit,
wherein the processing unit receives the remaining power capacity from the power management unit, and displays the remaining power capacity through the display unit.

8. A detection method of power capacity, adapted for an electronic device having a battery, and comprising:
reading an output voltage of the battery, and determining whether a variation of the output voltage of the battery within a time interval is greater than a first threshold; and
when determining that the variation of the output voltage of the battery within the time interval is greater than the first threshold, calculating a remaining power capacity of the battery according to the output voltage and the variation of the output voltage within the time interval.

9. The detection method of power capacity according to claim 8, wherein
the step of determining whether the variation of the output voltage of the battery within the time interval is greater than the first threshold comprises:
detecting a first instantaneous voltage and a second instantaneous voltage within the time interval, and obtaining the variation of the output voltage according to the first instantaneous voltage and the second instantaneous voltage; and
the step of calculating the remaining power capacity of the battery comprises:
calculating the remaining power capacity of the battery according to the second instantaneous voltage, the variation of the output voltage within the time interval, and a first recovery time.

10. The detection method of power capacity according to claim 9, wherein the step of determining whether the variation of the output voltage of the battery within the time interval is greater than the first threshold comprises:
when determining that the variation of the output voltage of the battery within the time interval is less than the first threshold, converting the second instantaneous voltage in order to obtain the remaining power capacity of the battery.

11. The detection method of power capacity according to claim 9, wherein the step of determining whether the variation of the output voltage of the battery within the time interval is greater than the first threshold further comprises:
determining whether the variation of the output voltage is greater than the first threshold and a second threshold, wherein the second threshold is greater than the first threshold;
when the variation of the output voltage is greater than the first threshold and the second threshold, calculating the remaining power capacity of the battery according to the second instantaneous voltage, a first preset variation, a first preset recovery interval, a second preset variation and a second preset recovery interval.

12. The detection method of power capacity according to claim 8, wherein
the first threshold is corresponding to one percent of a power capacity of the battery.

13. The detection method of power capacity according to claim 8, wherein before the step of reading the output voltage of the battery, and determining whether the variation of the output voltage of the battery within the time interval is greater than the first threshold, the detection method of power capacity further comprises:
determining whether the electronic device is enabled.

14. The detection method of power capacity according to claim 8, wherein after the step of calculating the remaining power capacity of the battery, the detection method of power capacity further comprises:
displaying the remaining power capacity of the battery through a display unit of the electronic device.
